(19) United States
(12) Patent Application Publication
(10) Pub. No.: US 2021/0313760 A1
(43) Pub. Date: Oct. 7, 2021

(54) METHOD FOR MANUFACTURING SEMICONDUCTOR LASER DIODE AND SEMICONDUCTOR LASER DIODE

(71) Applicant: ASAHI KASEI KABUSHIKI KAISHA, Tokyo (JP)

(72) Inventors: Kosuke SATO, Tokyo (JP); Motoaki IWAYA, Nagoya-shi (JP)

(73) Assignee: ASAHI KASEI KABUSHIKI KAISHA, Tokyo (JP)

(21) Appl. No.: 17/205,664

(22) Filed: Mar. 18, 2021

(30) Foreign Application Priority Data
Apr. 6, 2020 (JP) 2020-068544
Jan. 29, 2021 (JP) 2021-013292

(51) Int. Cl. H01S 5/02; H01S 5/028; H01S 5/40; H01S 5/042; H01S 5/227

(52) U.S. Cl. CPC H01S 5/0203; H01S 5/0287; H01S 5/2275; H01S 5/04254; H01S 5/4025

(57) ABSTRACT

To provide a Fabry-Perot semiconductor laser diode obtained through a step of forming a mirror facet using an etching technology, in which the threshold current density for laser oscillation is reduced.

A method for manufacturing a semiconductor laser diode includes a step of forming a plurality of semiconductor laser diodes on a substrate, and then dividing the substrate into each semiconductor laser diode. The method includes a step of forming a laminate containing a first semiconductor layer 21, a waveguide layer (first guide layer 22, light emitting layer 23, second guide layer 24), and a second semiconductor layer 25 in this order on a substrate 1, a step of etching the laminate to separate the laminate into a portion serving as a resonance region and the other portion, an electrode layer forming step of forming a layer 51 serving as a second electrode on the second semiconductor layer 25 of the laminate to between the mirror facet 200 of the resonance region and a position where the substrate 1 is divided in the dividing step, and, after the electrode layer forming step, an etching step of simultaneously or sequentially performing the removal of a portion 51a formed at a position on the outer side relative to the mirror facet 200 of the layer serving as the second electrode and the formation the mirror facet 200.

### BACKGROUND OF THE INVENTION

### Field of the Invention

The present invention relates to a method for manufacturing a semiconductor laser diode.

### Description of the Related Art

There are various types of semiconductor laser diodes due to a difference in the structure. One of the various types of semiconductor laser diodes includes a Fabry-Perot semiconductor laser diode resonating and amplifying light generated in a resonance region between the mirror facets.

As a method for forming the mirror facets, a method including performing cutting along the cleavage plane of a crystal and a method using an etching technology are mentioned. The method using the etching technology has been generally put into practical use because the method is applicable even when the cleavage planes of a substrate and a nitride semiconductor on the substrate are different, and thus has high versatility.

PTLS 1 and 2 describe methods for forming the mirror facets using the etching technology.

PTL 1 describes a problem that the mirror facets formed by dry etching are in a state of having defects due to damage caused by ions, which causes light absorption on the mirror facets. Further, in order to solve the problem, PTL 1 describes that the mirror surface degree of the mirror facets is improved by wet etching the dry-etched end surfaces with an etchant.

PTL 2 describes a semiconductor laser diode including a base layer as a first semiconductor layer, a resonance region formed on a part of the upper surface of the base layer and containing the first semiconductor layer, a first guide layer, a light emitting layer, a second guide layer, and a second semiconductor layer laminated in this order, a first electrode formed on a portion where the resonance region is not formed of the base layer, and a second electrode formed on the resonance region.

According to the method for manufacturing a semiconductor laser diode described in PTL 2, the laminate containing the first semiconductor layer, the first guide layer, the light emitting layer, the second guide layer, and the second semiconductor layer is formed on a substrate, and then the laminate is etched to separate the laminate into a portion serving as the resonance region and the other portion. Thereafter, the second electrode is formed on the second semiconductor layer and the first electrode is formed on the portion where the resonance region is not formed of the base layer by photolithography etching, a resist mask is formed with the width of the resonator length, and the mirror facets are formed by photolithography dry etching.

According to the method described in PTL 2, the mirror facets are formed by photolithography dry etching after the formation of the second electrode. Therefore, in the semiconductor laser diode manufactured by this method, the mirror facets and the end surfaces in the resonance direction of the resonance region of the second electrode are not in the same plane and the mirror facets are present on the outer side relative to the end surfaces of the electrode in a plan view.

On the other hand, one of the problems to be solved for the realization of an ultraviolet semiconductor laser diode is to increase the output. One of the approaches to achieve the output increase is to reduce the threshold current density for laser oscillation.

### CITATION LIST

### Patent Literature

PTL 1: JP 10-41585 A

PTL 2: JP 11-145566 A

PTL 3: JP 2008-124498 A

PTL 4: JP 2009-295952 A

PTL 5: JP 2020-47635 A

### SUMMARY OF THE INVENTION

It is an object of the present invention to provide a Fabry Perot semiconductor laser diode obtained through a step of forming mirror facets using an etching technology, in which the threshold current density for laser oscillation is reduced and the durability is improved.

In order to achieve the above-described object, a method for manufacturing a semiconductor laser diode according to a first aspect of the present invention has the following configurations (1) to (3).

(1) The method is a method for manufacturing a semiconductor laser diode including a base layer, a resonance region formed on a part of the upper surface of the base layer and containing a first semiconductor layer, a waveguide layer, and a second semiconductor layer laminated in this order, a first electrode formed on the first semiconductor layer near the resonance region, and a second electrode formed on the resonance region, in which the first semiconductor layer of the resonance region and the first semiconductor layer on which the first electrode is formed are continuous (both the first semiconductor layers are connected with no break). The waveguide layer includes a light emitting layer. The base layer may be a substrate or may be the first semiconductor layer formed on the substrate.
(2) The method includes a step of forming two or more of the semiconductor laser diodes on the substrate, and then dividing the substrate into each semiconductor laser diode.
(3) The method includes a step of forming a laminate containing the first semiconductor layer, the waveguide layer, and the second semiconductor layer in this order on the substrate.
(4) The method includes an electrode layer forming step of forming a layer serving as the second electrode on the second semiconductor layer of the laminate to between the mirror facet of the resonance region and the position where the substrate is divided in the dividing step and, after the electrode layer forming step, a first etching step of simultaneously or sequentially performing the removal of a portion formed at a position on the outer side relative to the mirror facet of the layer serving as the second electrode and the formation of the mirror facet.

A second aspect of the present invention is a semiconductor laser diode obtained by the manufacturing method of the first aspect and has the following configurations (11) and (12).

(11) The semiconductor laser diode includes a base layer, a resonance region formed on a part of a base region forming a part of the upper surface of the base layer and containing a first semiconductor layer, a waveguide layer, and a second semiconductor layer laminated in this order, a first electrode formed on the first semiconductor layer near the resonance region, a second electrode formed on the resonance region, and a projection portion projecting from both the surface constituting the mirror facet of the resonance region and the upper surface of the base region. The first semiconductor layer of the resonance region and the first semiconductor layer on which the first electrode is formed are continuous (both the first semiconductor layers are connected with no break).
(12) The projection portion directly shifts to the upper surface of the base region as a flat surface on the side away from the mirror facet.

The manufacturing method of the first aspect of the present invention can be expected to provide the semiconductor laser diode having a reduced threshold current density for laser oscillation and improved durability. Further, due to the fact that the method includes, after the electrode layer forming step, the etching step of simultaneously or sequentially performing the removal of each portion formed at the position on the outer side relative to the mirror facet of the layer serving as the second electrode and the formation of the mirror facets, an examination for examining the characteristics of each semiconductor laser diode can be performed before the dividing step.

The semiconductor laser diode of the second aspect of the present invention is the semiconductor laser diode obtained by the manufacturing method of the first aspect, which can be expected to obtain effects, such as a reduction in leakage current during current application, an increase in luminous efficiency, and an inhibition of irradiation pattern fluctuations because the projection portion projecting from both the surface constituting the mirror facet of the resonance region and the upper surface of the base region protects a portion where a current and heat are concentrated.

More specifically, the semiconductor laser diode of the second aspect of the present invention can be expected to have a reduced threshold current density for laser oscillation and improved durability.

### BRIEF DESCRIPTION OF DRAWINGS

FIGS. 1A to 1C each are figures illustrating each step constituting a method for manufacturing a semiconductor laser diode as one embodiment of the present invention and illustrate plan views of a substrate after each step and A-A cross-sectional views thereof.

FIGS. 2A to 2C each are figures illustrating each step constituting a method for manufacturing a semiconductor laser diode as one embodiment of the present invention, in which FIGS. 2A and 2B illustrate plan views of a substrate after each step and A-A cross-sectional views thereof and FIG. 2C illustrates a plan view and a front view of the substrate after the steps.

FIG. 3 is a plan view illustrating a substrate in a range where a plurality of nitride semiconductor laser diodes is formed and is a figure corresponding to the state of FIG. 2A.

FIG. 4 is a B-B cross-sectional view of FIG. 2C.

FIG. 5 is a perspective view of FIG. 2C.

FIG. 6 is a plan view illustrating a substrate in a range where a plurality of nitride semiconductor laser diodes is formed and is a figure corresponding to the state of FIG. 2C.

FIG. 7 is a cross-sectional view illustrating a semiconductor laser diode as one embodiment of the present invention.

### DESCRIPTION OF THE PREFERRED EMBODIMENTS

### [Findings of Present Inventors]

The present inventors have acquired knowledge that, when the mirror facets are formed using an etching technology, the mirror facets and the end surfaces in the resonance direction of the resonance region of the second electrode are not in the same plane and the mirror facets are present on the outer side relative to the electrode end surfaces in a plan view, which is one of factors that the threshold current density is high.

Further, the present inventors have found that, when an examination for examining the characteristics of each semiconductor laser diode by bringing a terminal connected to an external power supply into contact with the second electrode and the first electrode can be performed before the dividing step, a defective wafer can be removed and a manufacturing cost can be reduced.

### EMBODIMENTS

Hereinafter, embodiments of the present invention will be described, but the present invention is not limited to the embodiments described below. Although the embodiments described below are technically preferably limited for implementing the present invention, these limitations are not essential requirements of the present invention.

### [Configuration]

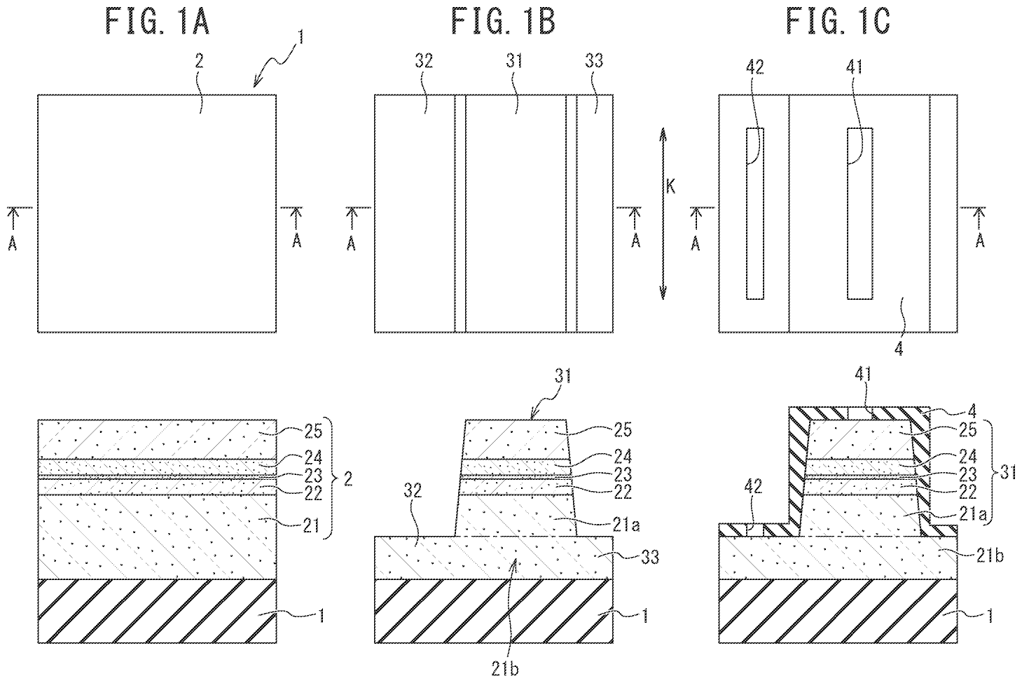

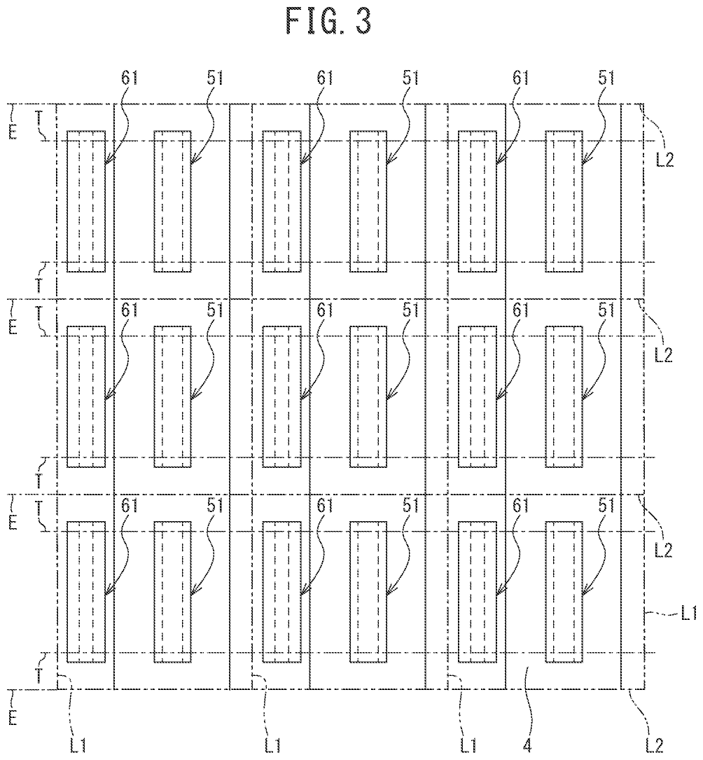

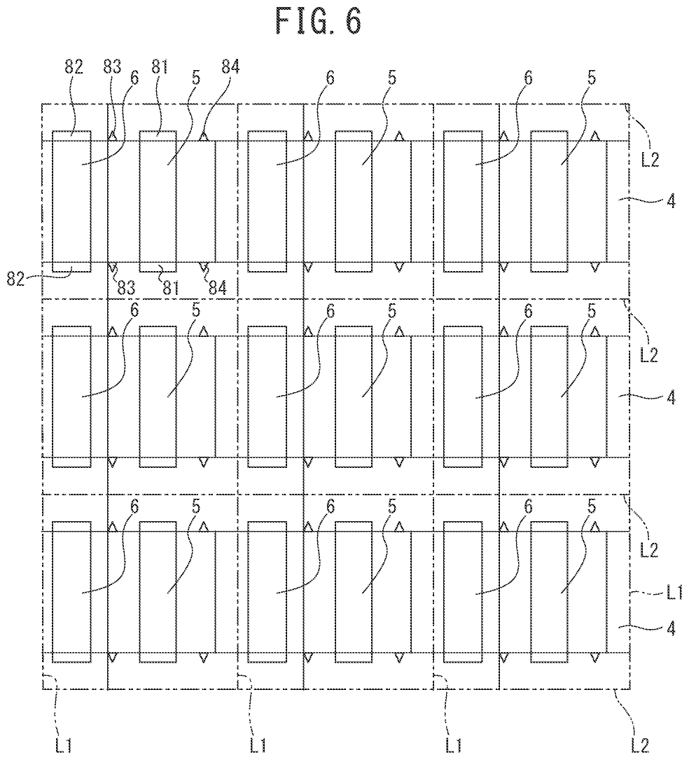

A method for manufacturing a Fabry-Perot semiconductor laser diode of this embodiment includes a step of forming a plurality of nitride semiconductor laser diodes on a substrate, and then dividing the substrate into each nitride semiconductor laser diode (hereinafter referred to as a “dividing step”). FIGS. 1A to 1C, 2A to 2C, 4, and 5 illustrate the substrate in a range where one nitride semiconductor laser diode is formed. FIGS. 3 and 6 illustrate the substrate in a range where the plurality of nitride semiconductor laser diodes is formed.

According to the method of this embodiment, a laminate 2 containing a first semiconductor layer 21, a first guide layer 22, a light emitting layer 23, a second guide layer 24, and a second semiconductor layer 25 in this order is first formed on a substrate 1 as illustrated in FIG. 1A. More specifically, the first guide layer 22, the light emitting layer 23, and the second guide layer 24 are formed as a waveguide layer.

A sapphire substrate is used as the substrate 1, an n-AlₓGa₍₁₋ₓ₎N layer is formed as the first semiconductor layer 21, and an AlₓGa₍₁₋ₓ₎N layer is formed as the first guide layer 22. An AlₓGa₍₁₋ₓ₎N layer is formed as the light emitting layer 23, an AlₓGa₍₁₋ₓ₎N layer is formed as the second guide layer 24, and a p-AlₓGa₍₁₋ₓ₎N layer is formed as the second semiconductor layer 25. More specifically, according to the method of this embodiment, a nitride semiconductor laser diode is manufactured.

Next, a mesa-etching step of etching the laminate 2 to separate the laminate into a mesa portion 31 (a portion containing a portion serving as a resonance region) and the other portion including a first portion 32 and a second portion 33 is performed as illustrated in FIG. 1B. As a result, the first semiconductor layer 21 is separated into a portion 21a constituting the mesa portion 31 (mesa side portion) and the other portion 21b in the film thickness direction. FIG. 1B illustrates a resonance direction K of the semiconductor laser diode to be manufactured.

Next, an insulating layer 4 as an SiO₂ layer is formed on the entire surface on the substrate 1 in the state of FIG. 1B, and then a through hole 41 for second electrode is provided in the insulating layer 4 on the second semiconductor layer 25 by a photolithography/etching step and, simultaneously therewith, a through hole 42 for first electrode is provided in the insulating layer 4 on the first portion 32. FIG. 1C illustrates the state after this step.

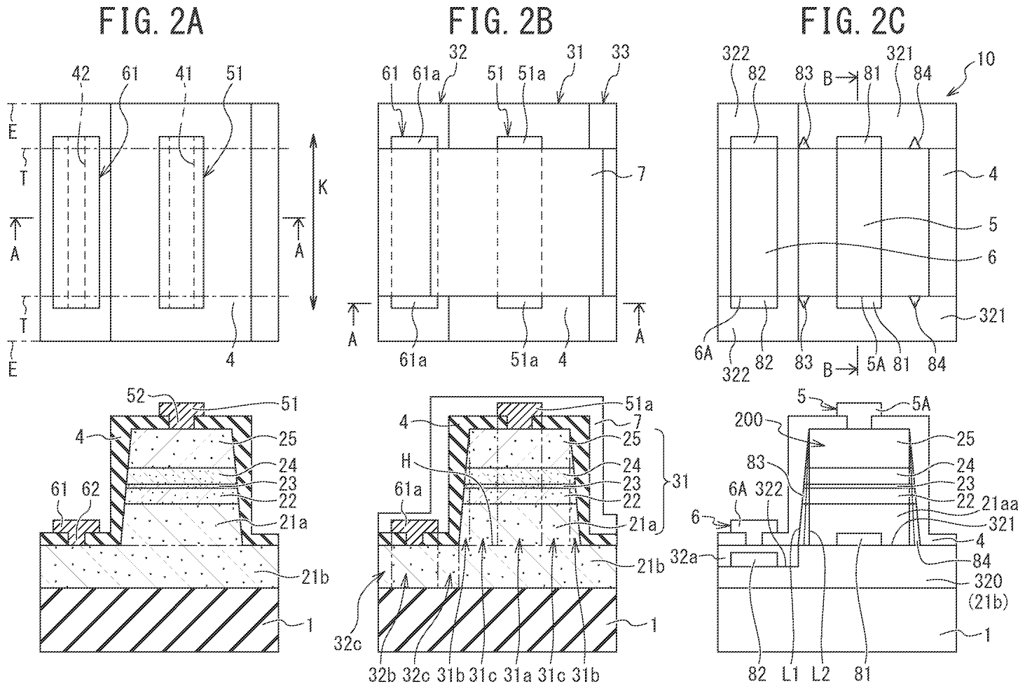

Next, a resist pattern is formed on the substrate 1 in the state of FIG. 1C, a lift-off step of depositing a Ni/Pt/Au layer, and then removing the resist pattern is performed, and then high-temperature heat treatment is performed, thereby forming a patterned NiPtAu alloy layer. Thus, the state illustrated in FIG. 2A is achieved. FIG. 2A illustrates the resonance direction K of the semiconductor laser diode to be manufactured and a pair of mirror facet positions T.

When this state is illustrated with the substrate 1 in the range where the plurality of nitride semiconductor laser diodes is formed, dividing lines L1, L2 are formed as illustrated in FIG. 3. Positions along the dividing lines L1, L2 are the positions where the substrate 1 is divided in the above-described dividing step. Among the dividing lines L1, L2, the positions of the dividing lines L2 orthogonal to the resonance direction K are designated by a reference numeral E in FIG. 3.

More specifically, in the above-described lithography/lift-off step, a second alloy layer (layer serving as a second electrode) 51 and a first alloy layer (layer serving as a first electrode) 61 are individually formed to between the mirror facet positions T and the positions E of the dividing lines L2 (positions where the substrate 1 is divided in the dividing step) in the resonance direction K as illustrated in FIGS. 2A and 3. At that time, a connector 52 electrically connecting the second alloy layer 51 and the second semiconductor layer 25 is formed in the through hole 41 for second electrode of the insulating layer 4 and a connector 62 electrically connecting the first alloy layer 61 and the second semiconductor layer 25 is formed in the through hole 42 for first electrode of the insulating layer 4.

Next, a Ni deposition film is formed on the substrate 1 in the state of FIG. 2A, and then a photolithography/lift-off step is performed, thereby achieving a state in which a portion between the pair of mirror facet positions T in the resonance direction K is covered with a Ni mask 7 as illustrated in FIG. 2B. In this state, the second alloy layer 51 and the first alloy layer 61 are individually brought into a state of being covered with the Ni mask 7 except for portions 51a and 61a on the outer side relative to the mirror facet positions T in the resonance direction K.

Next, the substrate 1 in the state illustrated in FIG. 2B undergoes dry etching. This dry etching is performed using chlorine gas under the condition that the mesa portion 31 is etched to a boundary position H between the first portion 32 and the second portion 33. By this one sequential dry etching step (first etching step), the outer portions 51a of the second alloy layer 51 and the outer portions 61a of the first alloy layer 61 are removed, so that end surfaces 5A of the second electrode 5 and end surfaces 6A of the first electrode 6 are generated as illustrated in FIG. 2C (i.e., the second electrode 5 and the first electrode 6 are formed) and a portion not covered with the mask 7 of the mesa portion 31 is removed to a predetermined depth, so that mirror facets 200 are formed. Further, the portion not covered with the mask 7 of the first portion 32 is also removed to a predetermined depth. As a result, the resonance region 310 and the base layer 320 are formed.

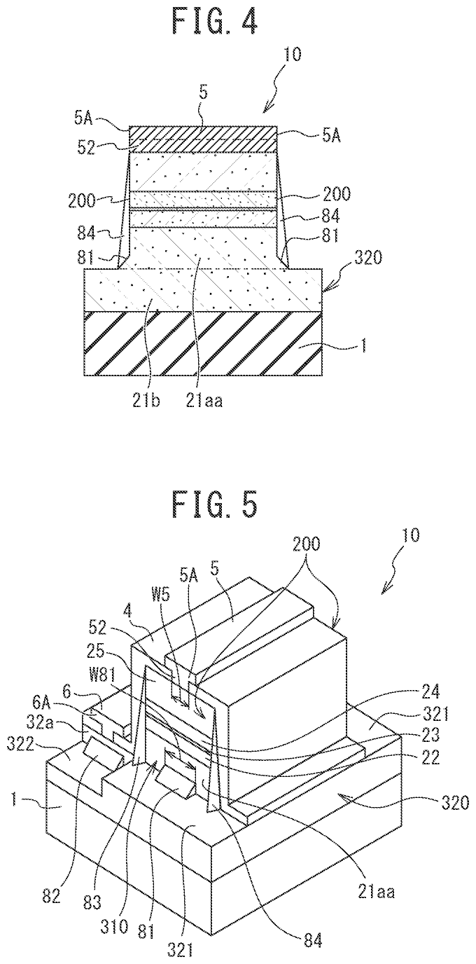

Next, the substrate 1 after the dry etching is immersed in an aqueous alkaline solution to undergo wet etching, and then the mask 7 is removed to obtain the substrate 1 (element precursor 10) in the state illustrated in FIG. 2C. The element precursor 10 is illustrated in a B-B cross-sectional view of FIG. 2C in FIG. 4 and in a perspective view in FIG. 5. When this state is illustrated with the substrate in the range where the plurality of nitride semiconductor laser diodes 10A is formed, the dividing lines L1, L2 are formed as illustrated in FIG. 6.

Next, the substrate 1 is divided along the dividing lines L1, L2 illustrated in FIG. 6, thereby obtaining each element precursor 10.

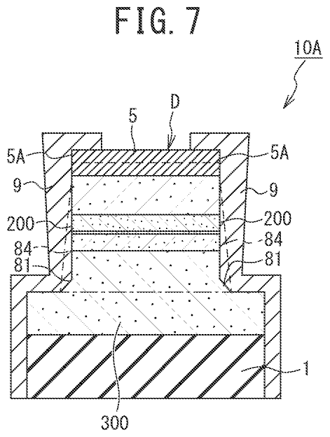

Next, as illustrated in FIG. 7, a reflection layer 9 which is a dielectric multilayer film of SiO₂ and HfO₂ is formed by a sputtering method on the mirror facets 200 of the element precursor 10, the end surfaces 5A of the second electrode 5, and the end surfaces 6A of the first electrode 6. Thus, the nitride semiconductor laser diode 10A illustrated in FIG. 7 is obtained.

The reflection layer 9 is formed in a state where a jig having an oblique surface tilting the surface of the substrate 1 by 45° is installed on a table where the substrate 1 is installed of a film forming device, and then the back surface of the substrate 1 is attached to the oblique surface of the jig to direct the mirror facets 200 of the element precursor 10 as film formation surfaces upward by 45° and a central portion in the resonance direction K of the upper surface of the element precursor 10 is covered with a cover. Thus, the reflection layer 9 is formed such that the film thickness on the end surfaces 5A of the second electrode 5 and the end surfaces 6A of the first electrode 6 is larger than the film thickness on the mirror facets 200 and conductive portions D are secured on the upper surfaces of the second electrode 5 and the first electrode 6.

As illustrated in FIGS. 2C, 4, and 5, the mirror facets 200 of the element precursor 10 (i.e., nitride semiconductor laser diode 10A) each contain the surfaces of a first semiconductor layer 21aa (a part of the mesa side portion 21a of the first semiconductor layer 2), the first guide layer 22, the light emitting layer 23, the second guide layer 24, and the second semiconductor layer 25. The end surfaces 5A in the resonance direction K of the second electrode 5 and the mirror facets 200 are present in the same planes. Further, the end surfaces 6A in the resonance direction K of the first electrode 6 and end surfaces 32a of the first portion (portion other than the mesa portion) 32 of the first semiconductor layer 21 are also present in the same planes as the planes of the mirror facets 200.

Further, the nitride semiconductor laser diode 10A has projection portions 81 to 84 formed by the dry etching to the substrate 1 in the state of FIG. 2B.

The projection portions 81 each project from both the surface of the first semiconductor layer 21aa constituting the mirror facet 200 and a first upper surface 321 of the base layer 320. The projection portions 82 each project from both the end surface 32a of the first semiconductor layer 21 present in the same plane as the end surface 6A in the resonance direction K of the first electrode 6 and a second upper surface 322 of the base layer 320.

The projection portions 81 each have a triangular prism shape. One side surface of the triangular prism is in contact with the first semiconductor layer 21aa constituting the mirror facet 200, another side surface is in contact with the first upper surface 321 of the base layer 320, and the other side surface is present upward as an oblique surface. More specifically, the projection portions 81 each have the largest projection dimension from the upper surface of the base layer 320 at the projection position from the surface of the first semiconductor layer 21aa constituting the mirror facet 200.

A dimension W81 in the direction orthogonal to the resonance direction K of the projection portion 81 is larger than a dimension W in the direction orthogonal to the resonance direction K of the connector 52.

The projection portions 83, 84 each project from both the surface, of a long and narrow right-angled triangle, containing the surfaces of all the layers (layers constituting the mesa portion 31) constituting the mirror facet 200, the long and narrow right-angled triangle containing an oblique line L1 indicating the oblique surface of the mesa portion 31, a perpendicular line L2 extending from the apex of the mesa portion 31 to the first upper surface 321 of the base layer 320, and a side along the first upper surface 321 (see the lower figure in FIG. 2C), and the triangular surface of the first upper surface 321 of the base layer 320 (see the upper figure in FIG. 2C). More specifically, the projection portions 83, 84 each have a triangular pyramid shape having side surfaces of a long and narrow triangular shape.

The projection portions 81, 83, 84 directly shift to the first upper surface 321 of the base layer 320 as a flat surface on the side away from the mirror facets 200. More specifically, in the nitride semiconductor laser diode 10A, the projection portions 81, 83, 84 are not present to the end surface position in the resonance direction K of the base layer 320 (for example, FIG. 5 of PTL 3, FIG. 2 of PTL 4) and the projection portions 81, 83, 84 do not shift to the first upper surface 321 via recessed portions (shift to the first upper surface 321 after the tips of the projection portions 81, 83, 84 are lowered to a position lower than the first upper surface 321) (for example, FIG. 3 of PTL 5).

The reason why the projection portions 81 to 84 are formed by the dry etching to the substrate 1 in the state of FIG. 2B is due to the fact that the dry etching rate using chlorine gas varies depending on the materials. For example, under a condition that the AlₓGa₍₁₋ₓ₎N layer is etched at 2.828 nm/s, the projection portions 81 to 84 are formed by the film formation performed under conditions that the etching rate of the SiO₂ layer is 0.585 nm/s and the etching rate of the NiPtAu alloy layer is 0.507 nm/s.

Herein, as illustrated in the lower figure of FIG. 2B, the portion not covered with the mask 7 of the mesa portion 31 is considered by dividing the portion into a central portion 31a serving as the lower side of the outer portion 51a of the second alloy layer 51, tilted portions 31b each containing a right-angled triangle having the tilted surface of the mesa portion 31 as the hypotenuse and the straight line indicating the boundary position H as the base, and end portions 31c each containing the rectangle between the central portion 31a and the tilted portion 31b.

More specifically, the etching rate of the mesa portion 31 as a laminate of the AlₓGa₍₁₋ₓ₎N layers is 5 times or more the etching rate of the NiPtAu alloy layer. Therefore, when the end portion 31c on which the portion 51a as the NiPtAu alloy layer is not present is etched to the boundary position H, the etching of the central portion 31a on which the portion 51a as the NiPtAu alloy layer is present is performed only to a position above the boundary position H at the position nearest to the mask 7 in the resonance direction K. As a result, the projection portions 81 are formed.

The insulating layer 4 is also formed on the oblique surfaces of the mesa portion 31, and therefore the etching of the tilted portions 31b is affected by the etching of the insulating layer 4 on the oblique surfaces. More specifically, portions of the tilted portions 31b etched after the etching of the insulating layer 4 on the oblique surfaces are enlarged toward the lower side of the tilted portion 31b. The etching rate of the mesa portion 31 as the laminate of the AlₓGa₍₁₋ₓ₎N layers is about 5 times the etching rate of the insulating layer 4 as the SiO₂ layer. Therefore, when the end portions 31c are etched to the boundary position H, parts of the tilted portions 31b in the resonance direction K are brought into an unetched state and remain as the projection portions 83, 84.

The portion not covered with the mask 7 of the first portion 32 is separated into a central portion 32b serving as the lower side of the outer portion 61a of the first alloy layer 61 and end portions 32c on both sides of the central portion 32b. The etching rate of the AlₓGa₍₁₋ₓ₎N layer is 5 times or more the etching rate of the NiPtAu alloy layer. Therefore, at the same time point, the etching depth of the end portions 32c on which the portion 61a as the NiPtAu alloy layer is not present is larger than the etching depth of the central portion 32b on which the portion 61a as the NiPtAu alloy layer is present.

More specifically, when the end portions 31c of the mesa portion 31 are etched to the boundary position H, the end portions 32c of the first portion 32 are etched to the second upper surface 322 lower than the first upper surface 321 of the base layer 320. However, the etching of the central portion 32b of the first portion 32 is performed only to the position above the second upper surface 322 at the position nearest to the mask 7 in the resonance direction K. As a result, the projection portions 82 are formed.

The reason why the projection portions 81 to 84 each have the triangular prism shape or the triangular pyramid shape is due to the fact that corner portions are intensively etched and cut away.

In the nitride semiconductor laser diode of this embodiment, the first alloy layer 61 and the second alloy layer 51 are formed of the same material. However, the first alloy layer 61 and the second alloy layer 51 may be formed of different materials. For example, even when the first alloy layer 61 is formed as a NiPtAu alloy layer and the second alloy layer 51 is formed as a V/Al/Ti/Au layer, a similar structure is formed.

### [Operations and Effects]

As described above, the method for manufacturing a nitride semiconductor laser diode of this embodiment includes an electrode layer forming step of forming the second alloy layer (layer serving as the second electrode) 51 on the second semiconductor layer 25 of the laminate 2 to between the mirror facet positions T of the resonance region 310 and the positions E where the substrate 1 is divided in the dividing step and, after the electrode layer forming step, an etching step of sequentially performing the removal of the portions 51a on the outer side relative to the mirror facet positions T in the resonance direction K of the second alloy layer (layer serving as the second electrode) 51 and the formation of the mirror facets 200.

Therefore, according to the method for manufacturing a nitride semiconductor laser diode of this embodiment, the nitride semiconductor laser diode 10A is obtained in which the mirror facets 200 and the end surfaces 5A in the resonance direction K of the second electrode 5 are present in the same planes. As a result, the nitride semiconductor laser diode 10A obtained by the manufacturing method of this embodiment can be expected to have a reduced threshold current density for laser oscillation.

The method for manufacturing a nitride semiconductor laser diode of this embodiment can provide the nitride semiconductor laser diode having the mirror facets 200 with a high degree of flatness by performing the above-described etching step by a dry etching method using the mask 7, and then performing wet etching with an aqueous alkaline solution without removing the mask 7.

According to the method for manufacturing a nitride semiconductor laser diode of this embodiment, both the second electrodes 5 and the first electrodes 6 are not continuous between adjacent element precursors in a state before the substrate 1 is divided by the dividing lines L1, L2 as illustrated in FIG. 6. Therefore, in the state illustrated in FIG. 6, an examination for examining the characteristics of each element by bringing a terminal connected to an external power supply into contact with the second electrode 5 and the first electrode 6 can be easily performed. On the other hand, when at least one of the second electrodes 5 and the first electrodes 6 is continuous between adjacent elements (for example, method described in PTL 3), correct examination cannot be performed by the above-described examination method because a plurality of elements is simultaneously driven. By performing this examination before the division, defective wafers can be removed and the manufacturing cost can be reduced. Further, when divided into the elements, the man-hours for arranging each element in an examination device in the examination significantly increase, which increases the manufacturing cost. In the case of an element in a wafer state, one wafer may be arranged, and therefore the cost can be sharply reduced.

The nitride semiconductor laser diode 10A of this embodiment includes the projection portions 81 each projecting from both the surface of the first semiconductor layer 21aa constituting the mirror facet 200 of the resonance region 310 and the first upper surface (base region) 321 of the base layer 320. The projection portions 81 each protect a portion where a current and heat are concentrated (surface of the first semiconductor layer 21aa constituting the mirror facet 200), so that the portion is less likely to be corroded by air, water, or the like. As a result, it can be expected to obtain effects, such as a reduction in a leakage current during current application, an increase in luminous efficiency, and an inhibition of irradiation pattern fluctuations.

Further, the projection portions 81 each have such a shape that the projection dimension from the first upper surface 321 of the base layer 320 is the largest at the projection position from the surface of the first semiconductor layer 21aa constituting the mirror facet 200 and the projection dimension decreases to zero with distance from this surface. Therefore, the projection portions 81 each can inhibit natural light emission and reflection/scattering of excess laser light while holding, at a high level, the effect of protecting the surface of the first semiconductor layer 21aa constituting the mirror facet 200.

Further, the dimension W81 in the direction orthogonal to the resonance direction K of the projection portions 81 is larger than a dimension W5 of the connector 52 corresponding to the width of a substantial light emitting portion. Therefore, the substantial light emitting portion is surely protected by the projection portions 81.

The nitride semiconductor laser diode 10A of this embodiment has the projection portions 82. The projection portions 82 each protect the end surface 32a damaged by etching of the first portion 32 of the first semiconductor layer 21, so that the end surfaces 32a are less likely to be corroded by air, water, or the like.

The nitride semiconductor laser diode 10A of this embodiment has the projection portions 83, 84. The projection portions 83, 84 each protect both end portions in the width direction of each layer constituting the mirror facet 200 damaged by etching, so that the portions are less likely to be corroded by air, water, or the like. As a result, it can be expected to obtain effects similar to that of the projection portion 81.

Further, due to the fact that the projection portions 81, 83, 84 directly shift to the first upper surface 321 of the base layer 320 as a flat surface on the side away from the mirror facets 200, it can be expected to obtain the following effects.

More specifically, the projection portions 81, 83, 84 are not present to the end surface position in the resonance direction K of the base layer 320 and the first upper surface 321 is present, and therefore the projection portions 81, 83, 84 are protected from damage due to a physical impact from the outside. For example, when the side surfaces of a chip are sandwiched between collets in assembling, the projection portions 81, 83, 84 can be prevented from directly contacting the collets, and therefore the breakage of the projection portions 81, 83, 84 is prevented. The same applies also to the projection portions 82.

The projection portions 81, 83, 84 are not present to the end surface position in the resonance direction K of the base layer 320 and the first upper surface 321 is present, and therefore, even when cracking or chipping occurs in the end surfaces of the element in the dividing step, the breakage of the projection portions 81, 83, 84 can be avoided. Further, the element dividing lines can be kept away from the light emitting portion of the semiconductor, and therefore damage to the light emitting portion due to heat or impact during division can be inhibited. The same applies also to the projection portions 82 when cracking or chipping occurs in the element end surfaces in the dividing step.

Further, the heat diffusion performance and the deterioration resistance performance are improved as compared with the case where the projection portions 81, 83, 84 shift to the first upper surface 321 via recessed portions on the side away from the mirror facets 200. This is because heat/current is/are concentrated and reaction with the outside air (oxygen, carbon) occurs, so that the semiconductor is likely to deteriorate in the base near these projection portions 81, 83, 84, but heat is easily diffused when no recessed portions are provided and the surface area becomes small corresponding to the absence of recessed portions, and thus the reaction with the outside air is less likely to occur, so that the deterioration is less likely to occur.

Natural light from the inside of the semiconductor is also emitted from the base layer 320. However, when the first upper surface 321 of the base layer 320 has irregularities, the light extraction efficiency of the natural light increases and the natural light acts as noise of laser light. Therefore, due to the fact that the projection portions 81, 83, 84 shift to the first upper surface 321 without via the recessed portions, the noise of the laser light can be reduced as compared with the case where the projection portions 81, 83, 84 shift to the first upper surface 321 via the recessed portions.

In the nitride semiconductor laser diode 10A of this embodiment, the reflection layer 9 is formed on the mirror facets 200 and the end surfaces 5A in the resonance direction K of the second electrode 5. The film thickness of the reflection layer 9 is larger in portions where the reflection layer 9 is formed on the end surfaces 5A of the second electrode 5 than in portions where the reflection layer 9 is formed on the mirror facets 200. More specifically, due to the formation of the reflection layer 9 having a large thickness capable of imparting a high corrosion inhibition effect on the end surfaces 5A of the second electrode 5 and the formation of the reflection layer 9 having a film thickness as designed (thinner than the reflection layer 9 formed on the end surfaces 5A) on the mirror facets 200, the durability of the nitride semiconductor laser diode is improved.

### [Differences Between First Aspect and Second Aspect and Embodiment]

The method for manufacturing a semiconductor laser diode of this embodiment performs the step, before the electrode layer forming step, of forming the insulating layer 4 on the second semiconductor layer 25 and the step of providing the through holes 41, 42 at the predetermined positions (corresponding to the electrode layer forming positions) of the insulating layer 4. As a result, the first electrode 6 and the first semiconductor layer 21 and the second electrode 5 and the second semiconductor layer 25 are connected by the connectors 62, 52, respectively. By performing the etching step via the insulating layer 4, the projection portions 83, 84 are formed in the semiconductor laser diode 10A to be obtained.

In the semiconductor laser diode 10A of this embodiment, the projection portions 83, 84 and the projection portions 81, 82 have the same projection dimension to the outer side in the resonance direction K. However, the projection dimensions may not be the same and, for example, the projection dimensions of the projection portions 83, 84 may be larger than those of the projection portions 81, 82.

According to the method for manufacturing a semiconductor laser diode of this embodiment, the range covered with the mask 7 in the resonance direction K is the same in the mesa portion 31 and in the first portion 32 and the second portion 33 other than the mesa portion 31 in the state of FIG. 2B. However, in the first portion 32, the entire upper surface may be covered. In that case, the first electrode 6 is formed such that the dimension in the resonance direction K is longer than that in the second electrode 5 and the second upper surface 322 and the projection portion 82 are not formed.

According to the method for manufacturing a semiconductor laser diode of this embodiment, the dry etching using the mask 7 is performed as the etching step of sequentially performing the removal of the portions 51a, 61a on the outer side of the mirror facet positions T of the second alloy layer 51 and the first alloy layer 61 and the formation of the mirror facets 200 but Focused Ion Beam (FIB) machining of emitting FIB ion beams to the outer side in the resonance direction K relative to the mirror facet positions T may be performed without using a mask in the state of FIG. 2A.

The semiconductor laser diode 10A of this embodiment does not have a ridge-portion semiconductor layer but may include the ridge-portion semiconductor layer above a part of the second semiconductor layer 25. By providing the ridge-portion semiconductor layer, a control can be performed so that the light emission in the light emitting layer is performed only in a region below the ridge-portion semiconductor layer. Therefore, the current density of the semiconductor laser diode can be further increased and the threshold value for laser oscillation can be further lowered.

According to the method for manufacturing a semiconductor laser diode of this embodiment, the laminate 2 is mesa-etched to separate the first semiconductor layer 21 into the portion 21a including the portion serving as the resonance region and the other portion 21b in the film thickness direction and the first electrode 6 is formed on the upper surface of the other portion 21b generated by this etching. More specifically, the formation surface of the first electrode 6 (second upper surface 322 of the base layer containing the first semiconductor layer) is formed by the mesa-etching. Thereafter, patterning using an etching mask different from that in the mesa-etching is performed, and then etching is performed again until the upper surface 321 of the base region reaches the position of the upper surface of the mesa-etched end surface 32a, so that the upper surface 321 of the base region serves as the upper surface of the first semiconductor layer 21. By performing the etching to the lower side relative to the base layer 320 containing the first semiconductor layer 21, for example, to the substrate 1, without adjusting the re-etching depth to the position of the upper surface of the end surface 32a, the upper surface 321 of the base region may serve as the upper surface of the substrate 1 instead of the upper surface of the first semiconductor layer 21.

### [Supplementary for Configurations of First Aspect and Second Aspect]

### (Substrate)

Specific examples of materials forming the substrate include Si, SiC, MgO, Ga₂O₃, Al₂O₃, ZnO, GaN, InN, AlN, or mixed crystals thereof. The substrate preferably has, but is not limited to, a rectangular thin plate in terms of assembling. The off-angle of the substrate is preferably larger than 0° and smaller than 2° from the viewpoint of growing high quality crystals. The film thickness of the substrate is not particularly limited when it is intended to laminate an AlGaN layer on the upper layer and is preferably 50 μm or more and 1 mm or less.

The substrate is used for the purpose of supporting thin films formed as layers constituting the semiconductor laser diode, improving the crystallinity, and dissipating heat to the outside. Therefore, it is preferable to use an AlN substrate which is a material capable of growing AlGaN with high quality and having high thermal conductivity.

The crystal quality of the substrate is not particularly limited. However, in order to form an element thin film having high luminous efficiency, the through-dislocation density is preferably 1×10⁹ cm⁻² or less and more preferably 1×10⁸ cm⁻² or less. The growth surface of the substrate is preferably a generally used +c-plane AlN due to its low cost but may be a −c-plane AlN, a semipolar plane substrate, or a nonpolar plane substrate. When a Group III composition gradient AlGaN widely used as a p-type semiconductor is grown, the +c-plane AlN is preferable from the viewpoint of increasing a polarization doping effect.

### (First Semiconductor Layer)

The thickness of the first semiconductor layer is not particularly limited. For example, the thickness of the first semiconductor layer may be 100 nm or more in order to reduce the resistance of the first semiconductor layer or may be 10 μm or less from the viewpoint of inhibiting the occurrence of cracks in the formation of the first semiconductor layer.

Examples of materials forming the first semiconductor layer include Al_{X1}Ga_{(1-X1)}N (0≤X1≤1). The materials forming the first semiconductor layer may contain impurities, such as Group V elements other than N, such as P, As, or Sb, Group III elements, such as In or B, and C, H, F, O, Si, Cd, Zn, or Be.

The Al composition ratio x of AlₓGa₍₁₋ₓ₎N can be specified by exposing a cross section along the a-plane of AlGaN using a Focused Ion Beam (FIB) device, observing the cross section under a transmission electron microscope, and performing energy dispersive X-ray analysis (EDX) of the cross section. The Al composition ratio x can be defined as a ratio of the number of moles of Al to the sum of the number of moles of Al and Ga and can be defined using a value of the number of moles of Al, Ga quantified by the EDX.

When the first semiconductor layer is an n-type semiconductor, an n-type can be achieved by doping 1×10¹⁹ cm⁻³ Si, for example. When the first semiconductor layer is a p-type semiconductor, a p-type can be achieved by doping 3×10¹⁹ cm⁻³ Mg, for example. The impurity concentration may be uniform or non-uniform throughout the layer, may be non-uniform only in the film thickness direction, or may be non-uniform only in the direction horizontal to the substrate.

Further, an intermediate layer, such as an AlN layer or an AlGaN layer, may be formed between the substrate 1 and the first semiconductor layer 21aa. In that case, this intermediate layer may be used as the base layer 320.

### (Waveguide Layer)

The waveguide layer is a layer including the light emitting layer and contains the first guide layer, the light emitting layer, and the second guide layer laminated in this order, for example and sometimes does not contain either or both of the first guide layer or/and the second guide layer.

### (First Guide Layer)

The first guide layer is formed on the first semiconductor layer. The first guide layer is imparted with a refractive index difference from the first semiconductor layer to confine light emitted in the light emitting layer in the light emitting portion (portion containing the first guide layer, the light emitting layer, and the second guide layer). Examples of materials forming the first guide layer include mixed crystals of AlN and GaN.

Specific examples of the materials forming the first guide layer include Alₓ₂Ga₍₁₋ₓ₂₎N (0<x2<1).

The Al composition ratio x2 of Alₓ₂Ga₍₁₋ₓ₂₎N forming the first guide layer may be smaller than the Al composition ratio x1 of Alₓ₁Ga₍₁₋ₓ₁₎N forming the first semiconductor layer. Thus, the first guide layer has a refractive index higher than that of the first semiconductor layer, and thus is enabled to confine light emitted in the light emitting layer in the light emitting portion. The materials forming the first guide layer may contain impurities, such as Group V elements other than N, such as P, As, or Sb, Group III elements, such as In or B, and C, H, F, O, Si, Cd, Zn, or Be.

When the first guide layer is an n-type semiconductor, an n-type can be achieved by doping 1×10¹⁹ cm⁻³ Si, for example. When the first guide layer is a p-type semiconductor, a p-type can be achieved by doping 3×10¹⁹ cm⁻³ Mg, for example. The first guide layer may have a dopant only in a part in the film thickness direction. More specifically, the n-type semiconductor and an undoped layer or the p-type semiconductor and an undoped layer may be combined in the part in the film thickness direction of the first guide layer. The first guide layer may be an undoped layer.

The first guide layer may have a structure in which the composition is graded. For example, the first guide layer may have a layer structure in which the Al composition ratio x2 of Alₓ₂Ga₍₁₋ₓ₂₎N is continuously or stepwise varied from 0.6 to 0.5. The thickness of the first guide layer is not particularly limited. The thickness of the first guide layer may be 10 nm or more to efficiently confine light emitted from the light emitting layer in the light emitting portion. The thickness of the first guide layer may be 2 μm or less from the viewpoint of reducing the resistance of the first guide layer.

The first guide layer may have an AlGaN layer serving as a block layer to the extent that the purpose of confining light in the light emitting portion is held.

### (Light Emitting Layer)

Examples of materials forming the light emitting layer include AlN, GaN, and a mixed crystal thereof. Specific examples of the materials forming the light emitting layer include Alₓ₃Ga₍₁₋ₓ₃₎N (0≤x3≤1). The Al composition ratio x3 of Alₓ₃Ga₍₁₋ₓ₃₎N in the light emitting layer may be smaller than the Al composition ratio x2 of Alₓ₂Ga₍₁₋ₓ₂₎N in the first guide layer to efficiently confine carriers injected from the first electrode and the second electrode in the light emitting portion. For example, the light emitting layer may be formed of Alₓ₃Ga₍₁₋ₓ₃₎N in which the Al composition ratio x3 satisfies the relationship of 0.2≤x3<1.

The materials forming the light emitting layer may contain impurities, such as Group V elements other than N, such as P, As, or Sb, Group III elements, such as In or B, and C, H, F, O, Si, Cd, Zn, or Be.

When the light emitting layer is an n-type semiconductor, an n-type can be achieved by doping 1×10¹⁹ cm⁻³ Si, for example. When the light emitting layer is a p-type semiconductor, a p-type can be achieved by doping 3×10¹⁹ cm⁻³ Mg, for example. The light emitting layer may be an undoped layer.

The light emitting layer may have a Multiple Quantum Well (MQW) structure which has a well layer formed of, for example, Alₓ₅Ga₍₁₋ₓ₅₎N and a barrier layer provided adjacent to the well layer and formed of, for example, Alₓ₄Ga₍₁₋ₓ₄₎N and in which the well layers and the barrier layers are alternately stacked one by one.

The Al composition ratio x5 of the well layer is smaller than the Al composition ratio x4 of each of the first guide layer and the second guide layer. The Al composition ratio x5 of the well layer is smaller than the Al composition ratio x4 of the barrier layer. The Al composition ratio x4 of the barrier layer may be the same as the Al composition ratio x4 of each of the first guide layer and the second guide layer or may be higher or lower than the Al composition ratio x4 of each of the first guide layer and the second guide layer.

The average Al composition ratio of the well layers and the barrier layers is the Al composition ratio x of the light emitting layer. Due to the fact that the light emitting layer having the multiple quantum well structure is provided, the luminous efficiency or the luminous intensity of the light emitting layer can be improved.

The light emitting layer may have a double quantum well structure of “Barrier layer/Well layer/Barrier layer/Well layer/Barrier layer”, for example. The film thickness of each of these well layers may be 4 nm, for example, the film thickness of each of these barrier layers may be 8 nm, for example, and the film thickness of the light emitting layer may be 32 nm. The number of quantum wells in the multiple quantum well layer may be one layer (i.e., a single quantum well instead of the multiple quantum well) or may be two layers, three layers, four layers, or five layers. The single well layer is preferable for the purpose of increasing the carrier density within one well layer.

### (Second Guide Layer)

The second guide layer is formed on the light emitting layer. The second guide layer is imparted with a refractive index difference from the second semiconductor layer to confine light emitted in the light emitting layer in the light emitting portion. Examples of materials forming the second guide layer include AlN, GaN, and a mixed crystal thereof. Specific examples of the materials forming the second guide layer include Alₓ₆Ga₍₁₋ₓ₆₎N (0≤x6≤1).

The Al composition ratio x6 of Alₓ₆Ga₍₁₋ₓ₆₎N in the second guide layer may be larger than the Al composition ratio x5 of Alₓ₅Ga₍₁₋ₓ₅₎N in the well layer. Thus, carriers can be confined in the light emitting layer. The materials forming the second guide layer may contain impurities, such as Group V elements other than N, such as P, As, or Sb, Group III elements, such as In or B, and C, H, F, O, Si, Cd, Zn, or Be.

When the second guide layer is an n-type semiconductor, an n-type can be achieved by doping 1×10¹⁹ cm⁻³ Si, for example. When the second guide layer is a p-type semiconductor, a p-type can be achieved by doping 3×10¹⁹ cm⁻³ Mg, for example. The second guide layer may be an undoped layer. The second guide layer may have a structure in which the Al composition ratio x6 of Alₓ₆Ga₍₁₋ₓ₆₎N is graded. For example, the second guide layer may have a layer structure in which the Al composition ratio x6 of Alₓ₆Ga₍₁₋ₓ₆₎N is continuously or stepwise varied from 0.5 to 0.6.

The thickness of the second guide layer is not particularly limited. The thickness of the second guide layer may be 10 nm or more to efficiently confine light emitted from the light emitting layer in the light emitting portion. Further, the thickness of the second guide layer may be 2 μm or less from the viewpoint of reducing the resistance of the second guide layer.

The Al composition ratio x6 of Alₓ₆Ga₍₁₋ₓ₆₎N (0≤x6≤1) in the second guide layer and the Al composition ratio x4 of Alₓ₄Ga₍₁₋ₓ₄₎N (0≤x4≤1) in the first guide layer may have the same value or different values.

### (Second Semiconductor Layer)

When the second semiconductor layer is an n-type semiconductor, an n-type can be achieved by doping 1×10¹⁹ cm⁻³ Si, for example. When the second semiconductor layer is a p-type semiconductor, a p-type can be achieved by doping 3×10¹⁹ cm⁻³ Mg, for example. The dopant concentration may be uniform or non-uniform in the vertical direction of the substrate. The dopant concentration may be uniform or non-uniform in the in-plane direction of the substrate.

The second semiconductor layer may have a structure in which the Al composition ratio of AlGaN is graded. When the second semiconductor layer has a layer structure, the second semiconductor layer may not contain a dopant or may be an undoped layer. The second semiconductor layer may have a laminated structure of further having a layer having a high doping concentration in the uppermost layer.

The second semiconductor layer may have a laminated structure of two or more layers. In that case, for the purpose of efficiently transporting carriers to the light emitting layer, the Al composition ratio preferably becomes smaller toward the upper layer.

The Al composition ratio x7 of Alₓ₇Ga₍₁₋ₓ₇₎N of the materials forming the second semiconductor layer may be 0. The use of p-type (p-)GaN in which the Al composition ratio x7 of Alₓ₇Ga₍₁₋ₓ₇₎N is 0 for the uppermost layer of the second semiconductor layer can reduce the contact resistance of the second electrode arranged on the second semiconductor layer.

### (First Electrode)

When the first electrode is an n-type electrode, materials corresponding to an n-type electrode of a common nitride semiconductor light emitting element are usable as materials forming the first electrode in a case where the first electrode is used for the purpose of injecting electrons into the first semiconductor layer. For example, Ti, Al, Ni, Au, Cr, V, Zr, Hf, Nb, Ta, Mo, W, and alloys thereof, ITO, and the like are applied as the formation materials when the first electrode is an n-type electrode.

When the first electrode is a p-type electrode, the same materials as those of a p-type electrode layer of a common nitride semiconductor light emitting element are usable as materials forming the first electrode in a case where the first electrode is used for the purpose of injecting holes into the nitride semiconductor light emitting element. For example, Ni, Au, Pt, Ag, Rh, Pd, Cu, and alloys thereof, ITO, and the like are applied as the formation materials when the first electrode is a p-type electrode. When the first electrode is a p-type electrode, Ni, Au, or an alloy thereof, or ITO having a small contact resistance between the first electrode and a ridge-portion semiconductor layer 17 may be acceptable.

The first electrode may have a pad electrode in the upper part for the purpose of uniformly diffusing a current over the entire region of the first electrode. Examples of materials forming the pad electrode include Au, Al, Cu, Ag, W, and the like. The pad electrode may be formed of Au having high conductivity among these materials from the viewpoint of conductivity.

Specifically, as the structure of the first electrode, a structure is mentioned in which a first contact electrode formed of an alloy of Ni and Au is formed on the first semiconductor layer and a first pad electrode formed of Au is formed on the first contact electrode, for example.

The first electrode is formed to have a thickness of 240 nm, for example.

### (Second Electrode)

When the second electrode is an n-type electrode, materials corresponding to an n-type electrode of a common semiconductor laser diode are usable as materials forming the second electrode in a case where the second electrode is used for the purpose of injecting electrons into the first semiconductor layer. For example, Ti, Al, Ni, Au, Cr, V, Zr, Hf, Nb, Ta, Mo, W, and alloys thereof, ITO, and the like are applied as the formation materials when the second electrode is an n-type electrode.

When the second electrode is a p-type electrode, the same materials as those of a p-type electrode layer of a common nitride semiconductor light emitting element are usable as materials forming the second electrode in a case where the second electrode is used for the purpose of injecting holes into the nitride semiconductor light emitting element. For example, Ni, Au, Pt, Ag, Rh, Pd, Cu, and alloys thereof, ITO, and the like are applied as the formation materials when the second electrode is a p-type electrode. When the second electrode is a p-type electrode, Ni, Au, or an alloy thereof, or ITO having a small contact resistance between the second electrode and the second semiconductor layer may be acceptable.

The second electrode may have a pad electrode in the upper part for the purpose of uniformly diffusing a current over the entire region of the second electrode. Examples of materials forming the pad electrode include Au, Al, Cu, Ag, W, and the like. The pad electrode may be formed of Au having high conductivity among these materials from the viewpoint of conductivity. Specifically, as the structure of the second electrode, a structure is mentioned in which a second contact electrode formed of an alloy of materials selected from Ti, Al, Ni, and Au is formed on the second semiconductor layer and a second pad electrode formed of Au is formed on the second contact electrode, for example.

The second electrode is formed to have a thickness of 60 nm, for example. The second electrode and the first electrode may be formed to have different thicknesses or may be formed to have the same thickness.

### Reference Sings List

1 substrate
2 laminate
21 first semiconductor layer
21a mesa side portion of first semiconductor layer (portion constituting mesa portion of first semiconductor layer)
21aa portion serving as resonator region of first semiconductor layer (first semiconductor layer constituting mirror facet)
21b portion serving as base layer of first semiconductor layer
22 first guide layer (waveguide layer)
23 light emitting layer (waveguide layer)
24 second guide layer (waveguide layer)
25 second semiconductor layer
31 mesa portion (portion containing portion serving as resonator region)
32 first portion (portion other than mesa portion)
33 second portion (portion other than mesa portion)
4 insulating layer
5 second electrode
5A end surface in resonance direction of second electrode
21 second alloy layer (layer serving as second electrode)
51a portion of second alloy layer formed on outer side relative to mirror facet position
52 connector
6 first electrode
6A end surface in resonance direction of first electrode
61 first alloy layer (layer serving as first electrode)
61a portion of first alloy layer formed on outer side relative to mirror facet position
62 connector
7 mask
81 projection portion
82 projection portion
83 projection portion
84 projection portion
9 reflection layer
200 mirror facet
310 resonance region
320 base layer
321 first upper surface of base layer
322 second upper surface of base layer
K resonance direction

1. A method for manufacturing a semiconductor laser diode including a base layer, a resonance region formed on a part of an upper surface of the base layer and containing a first semiconductor layer, a waveguide layer, and a second semiconductor layer laminated in this order, a first electrode formed on the first semiconductor layer near the resonance region, and a second electrode formed on the resonance region,
the first semiconductor layer of the resonance region and the first semiconductor layer on which the first electrode is formed being continuous,
the method comprising:
forming two or more of the semiconductor laser diodes on a substrate, and then dividing the substrate into each semiconductor laser diode;
forming a laminate containing the first semiconductor layer, the waveguide layer, and the second semiconductor layer in this order on the substrate;
an electrode layer forming step of forming a layer serving as the second electrode on the second semiconductor layer of the laminate to between a mirror facet of the resonance region and a position where the substrate is divided in the dividing step; and
after the electrode layer forming step, a first etching step of simultaneously or sequentially performing removal of a portion formed at a position on an outer side relative to the mirror facet of the layer serving as the second electrode and formation of the mirror facet.

2. The method for manufacturing a semiconductor laser diode according to claim 1, further comprising:
a mesa-etching step of etching the laminate to separate the first semiconductor layer into a portion containing a portion serving as the resonance region and another portion in a film thickness direction, wherein
the first electrode is formed on an upper surface of the another portion generated by this etching.

3. The method for manufacturing a semiconductor laser diode according to claim 1, wherein
the first etching step is performed by a dry etching method using a mask, and
after the first etching step, wet etching is performed with an aqueous alkaline solution without removing the mask.

4. A semiconductor laser diode comprising:
a base layer;
a resonance region formed on a part of a base region forming a part of an upper surface of the base layer and containing a first semiconductor layer, a waveguide layer, and a second semiconductor layer laminated in this order;
a first electrode formed on the first semiconductor layer near the resonance region;
a second electrode formed on the resonance region; and
a projection portion projecting from both a surface constituting a mirror facet of the resonance region and an upper surface of the base region, wherein
the first semiconductor layer of the resonance region and the first semiconductor layer on which the first electrode is formed are continuous, and
the projection portion directly shifts to the upper surface of the base region as a flat surface on a side away from the mirror facet.

5. The semiconductor laser diode according to claim 4, wherein
the mirror facet and an end surface in a resonance direction of the resonance region of the second electrode are in a same plane.

6. The semiconductor laser diode according to claim 4, wherein
the projection portion has a largest projection dimension from the upper surface of the base layer at a projection position from the surface constituting the mirror facet.

7. The semiconductor laser diode according to claim 4, wherein
the second electrode is formed on the second semiconductor layer via an insulating layer,
a connector electrically connecting the second electrode and the second semiconductor layer is formed in a through hole of the insulating layer, and
a dimension in a direction orthogonal to the resonance direction of the resonance region is larger in the projection portion than in the connector.

8. The semiconductor laser diode according to claim 4, wherein
a reflection layer is formed on the mirror facet and the end surface in the resonance direction of the resonance region of the second electrode, and a film thickness of the reflection layer is larger in the end surface of the second electrode than in the mirror facet.

9. The method for manufacturing a semiconductor laser diode according to claim 2, wherein
the first etching step is performed by a dry etching method using a mask, and
after the first etching step, wet etching is performed with an aqueous alkaline solution without removing the mask.

10. The semiconductor laser diode according to claim 5, wherein
the projection portion has a largest projection dimension from the upper surface of the base layer at a projection position from the surface constituting the mirror facet.

11. The semiconductor laser diode according to claim 5, wherein
the second electrode is formed on the second semiconductor layer via an insulating layer,
a connector electrically connecting the second electrode and the second semiconductor layer is formed in a through hole of the insulating layer, and
a dimension in a direction orthogonal to the resonance direction of the resonance region is larger in the projection portion than in the connector.

12. The semiconductor laser diode according to claim 6, wherein
the second electrode is formed on the second semiconductor layer via an insulating layer,
a connector electrically connecting the second electrode and the second semiconductor layer is formed in a through hole of the insulating layer, and
a dimension in a direction orthogonal to the resonance direction of the resonance region is larger in the projection portion than in the connector.

13. The semiconductor laser diode according to claim 5, wherein
a reflection layer is formed on the mirror facet and the end surface in the resonance direction of the resonance region of the second electrode, and a film thickness of the reflection layer is larger in the end surface of the second electrode than in the mirror facet.

14. The semiconductor laser diode according to claim 6, wherein
a reflection layer is formed on the mirror facet and the end surface in the resonance direction of the resonance region of the second electrode, and a film thickness of the reflection layer is larger in the end surface of the second electrode than in the mirror facet.

15. The semiconductor laser diode according to claim 7, wherein
a reflection layer is formed on the mirror facet and the end surface in the resonance direction of the resonance region of the second electrode, and a film thickness of the reflection layer is larger in the end surface of the second electrode than in the mirror facet.
